(19) United States
(12) Patent Application Publication
(10) Pub. No.: US 2024/0038556 A1
(43) Pub. Date: Feb. 1, 2024

(54) METHOD FOR MITIGATING WARPAGE ON STACKED WAFERS

(71) Applicant: XILINX, INC., San Jose, CA (US)

(72) Inventors: Myongseob KIM, Pleasanton, CA (US); Henley LIU, San Jose, CA (US); Cheang-whang CHANG, Mountain View, CA (US)

(21) Appl. No.: 17/875,226

(22) Filed: Jul. 27, 2022

(51) Int. Cl. H01L 21/67; H01L 21/66; H01L 25/065

(52) U.S. Cl. CPC H01L 21/67288; H01L 21/67253; H01L 22/12; H01L 25/0657

(57) ABSTRACT

Methods for mitigating warpage on stacked wafers are provided herein. In one example, a method for mitigating warpage on stacked wafers includes depositing a first warpage compensating layer on a backside of a first wafer, stacking an active side of the first wafer on an active side of a second wafer to form a wafer stack having circuitry of the first wafer electrically connected to circuitry of the second wafer, and removing the first warpage compensating layer from the backside of the first wafer prior dicing the wafer stack.

### TECHNICAL FIELD

Embodiments of the present invention generally relate to methods for fabricating stacked wafers and chip packages using one or more warpage compensating layers.

### BACKGROUND

Electronic devices, such as tablets, computers, copiers, digital cameras, smart phones, control systems, automated teller machines, data centers, artificial intelligence system, and machine learning systems among others, often employ electronic components which leverage chip package assemblies for increased functionality and higher component density. Conventional chip packaging schemes often utilize a package substrate, often in conjunction with a through-silicon-via (TSV) interposer substrate, to enable a plurality of integrated circuit (IC) dies to be mounted to a single package substrate. The IC dies may include memory, logic or other IC devices.

Out of plane deformation of the chip package can be problematic to conventional chip packaging schemes. In chip packages, the differences in the materials stacked on a package substrate to form the chip package can undesirably contribute to warpage. Mismatches between the coefficient of thermal expansion between these materials often generates a bending moment to the package substrate, and thus the chip package. The high stress produced by the bending movement promotes out of plane deformation. The resulting warpage and bending of the chip package can lead to solder connection failure or other damage to the components and devices of the chip package, which may detrimentally affect device performance and reliability.

In addition, wafers having a high number of metal layers have an increased propensity for warpage. When wafers are stacked, problems associated with warpage will increase, typically becoming worse as more wafers are stacked together. When warpage exceeds processing tool (i.e., lithography, chemical vapor deposition tools, physical vapor deposition tools, and the like) specifications, further processing cannot be performed, leading to expensive the scrapping of the wafer stack. Conventional techniques for mitigation wafer warpage typically employ tuning the stress of the dielectric films deposited on the wafer using chemical vapor deposition (CVD). However, the amount of warpage that can be tuned out of CVD dielectric films is limited due to the physical properties of the film and limitations in thickness due to design constraints. Moreover, the CVD dielectric films must be compatible with subsequent process steps without losing the stress tuning properties or otherwise becoming unreliable. Furthermore, since warpage issues are difficult to predict in the early design stages, changing the dielectric film deposition process after initial prototype fabrication runs can be very costly and often incur significant time delays.

Therefore, a need exists for an improved method for stacking wafers that mitigates warpage.

### SUMMARY

Methods for mitigating warpage on stacked wafers are provided herein. In one example, a method for mitigating warpage on stacked wafers includes depositing a first warpage compensating layer on a backside of a first wafer, stacking an active side of the first wafer on an active side of a second wafer to form a wafer stack having circuitry of the first wafer electrically connected to circuitry of the second wafer, and removing the first warpage compensating layer from the backside of the first wafer prior dicing the wafer stack.

In another example, a method for mitigating warpage on stacked wafers includes stacking a plurality of wafers to form a wafer stack, wherein the wafers within the wafer stack each have circuitry that is electrically connected to at least one other wafer of the wafer stack, wherein stacking the plurality of wafers includes stacking an active side of a first wafer on an active side of a second wafer, the first wafer having circuitry electrically connected to circuitry of the second wafer; depositing, after forming the wafer stack, a warpage compensating layer on a top or a bottom the wafer stack, the warpage compensating layer not electrically connected to circuitry of any of the wafers of the wafer stack; and dicing the wafer stack.

In another example, a method for mitigating warpage on stacked wafers includes stacking an active side of a first wafer on an active side of a second wafer, the first wafer having circuitry electrically connected to circuitry of the second wafer; depositing a dielectric warpage compensating layer on a backside of the second wafer; thinning the second wafer and removing the warpage compensating layer from the backside of the second wafer prior; stacking an active side of a third wafer on backside of the thinned second wafer to form a wafer stack comprising the first, second and third wafers, the third wafer having circuitry electrically connected to circuitry of the second wafer; and dicing the wafer stack.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a flow diagram of a method for forming a chip package that includes a method for two or more stacking wafers.

FIGS. 2A-K are schematic representations of wafers being stacked, diced to form stacked IC devices, and mounting at least one of the stacked IC devices to form a chip package in accordance to the method of FIG. 1.

FIG. 3 is a flow diagram of another method for forming a chip package that includes a method for two or more stacking wafers.

FIGS. 4A-F are schematic representations of wafers being stacked, diced to form stacked IC devices, and mounting at least one of the stacked IC devices to form a chip package in accordance to the method of FIG. 3.

To facilitate understanding, identical reference numerals have been used, where possible, to designate identical elements that are common to the figures. It is contemplated that elements of one embodiment may be beneficially incorporated in other embodiments.

### DETAILED DESCRIPTION

Techniques are described herein that mitigate warpage when stacking wafers that are later diced to form chip stacks for use in chip packages. The techniques employ a warpage compensation film deposited on a backside of a wafer prior to or after wafer stacking. In most cases, the warpage compensation film is removed after forming an initial wafer stack to facilitate stacking of additional wafers. Optionally, the warpage compensation film may be left exposed on top of the last wafer stacked. The warpage compensation film is removed prior to stacking another wafer such that the warpage compensation film is never buried within the wafer stack. The warpage compensation film provides significant flexibility and freedom for material choice, properties, and thickness to enable warpage to be more effectively addressed with little impact on the film stack deposited on each wafer that are part of the functional design of the integrated circuit (IC) device being formed on the wafer, as compared to using conventional tuned CVD processes to address warpage. The compensation film and techniques described herein enable a high number of metal layers to be utilized in IC device designs without exceeding warpage specifications. Furthermore, since the warpage compensation film can be added to process flows without modifying the films used in the IC device itself, warpage issues may be quickly and cost effectively addressed at any portion of the design cycle. As a result, more robust chip packages that incorporate chip stacks are enabled, while reducing both cost and development time to market.

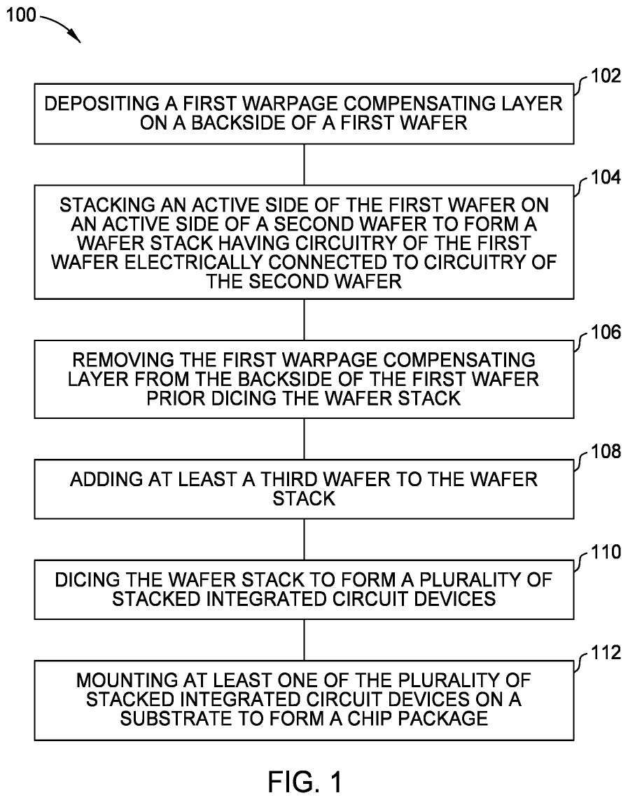

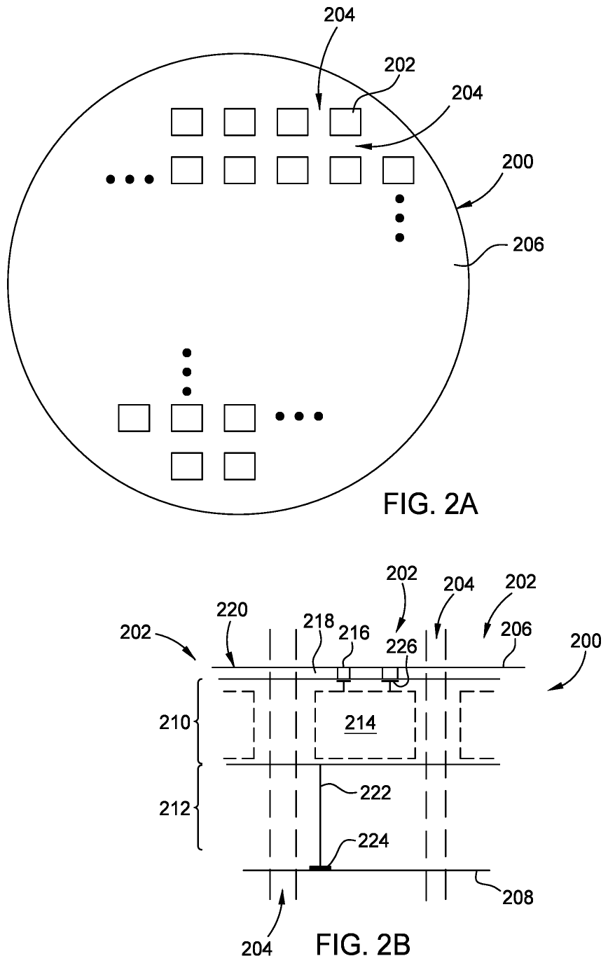

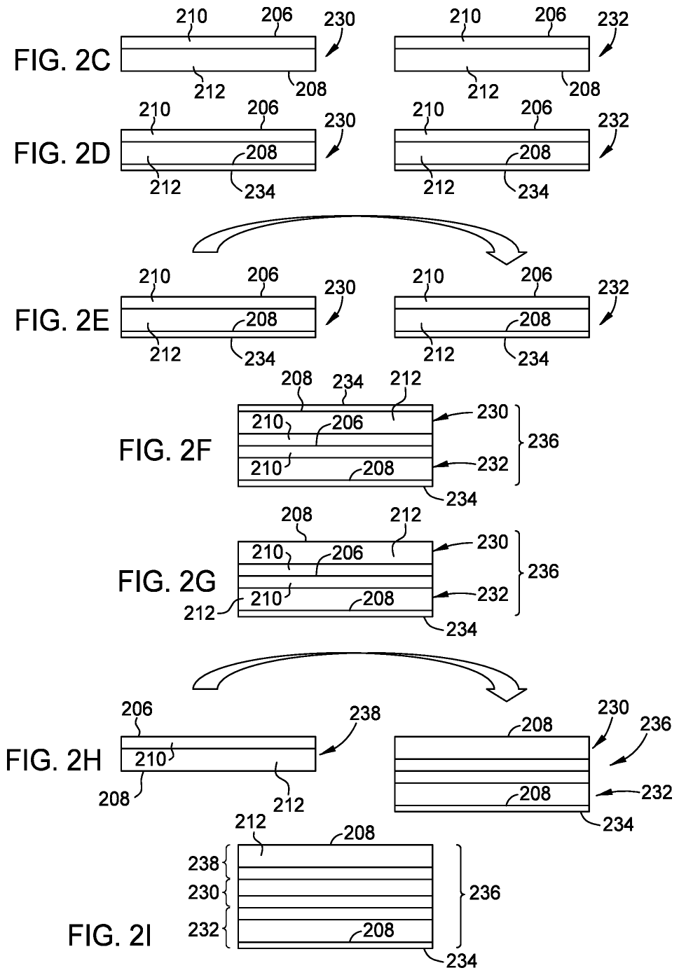

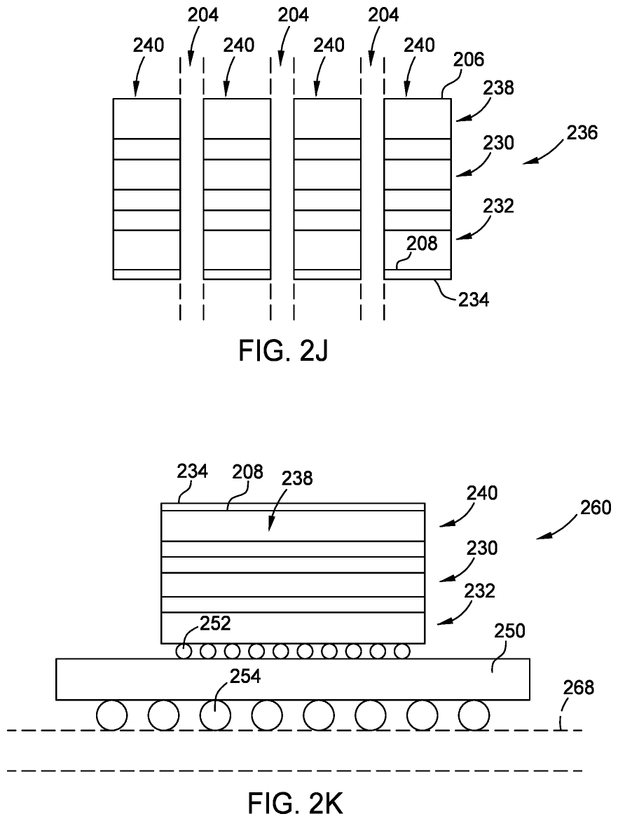

Turning now to FIG. 1, a flow diagram of a method 100 for forming a chip package is provided. The chip package may be configured as shown in 2K, or in another suitable configuration. FIGS. 2A-K are schematic representations of wafers being stacked, diced to form stacked IC devices, and mounting at least one of the stacked IC devices to form a chip package in accordance to the method 100 of FIG. 1.

An exemplary wafer 200 that may be utilized to perform the method 100 is illustrated in FIG. 2A. The method 100 may also be performed with wafers having other configurations. The wafer 200 generally include a plurality of integrated circuit (IC) dies 202 formed on an active side 206 of the wafer 200. The plurality of IC dies 202 are separated by scribe lanes 204. The wafer 200 is sawn or otherwise cut along the scribe lanes 204 to separate neighboring IC dies 202 from each other. Optionally, some neighboring IC dies 202 may be left connected together after dicing.

As further illustrated in the partial sectional view of the wafer 200 depicted in FIG. 2B, each IC die 202 includes functional circuitry 214 formed in the active portion 210 of the wafer 200. The active portion 210 includes front end of line integrated circuit structures, such as transistors and the like, and back end of the line interconnect structures, such as dual damascenes and/or other interconnect routings. The functional circuitry 214 of the IC dies 202 may include block random access memory (BRAM), UltraRAM (URAM), digital signal processing (DSP) blocks, configurable logic elements (CLEs), and the like. The IC dies 202 containing the functional circuitry 214 may be, but are not limited to, programmable logic devices, such as field programmable gate arrays (FPGA), memory devices, such as high band-width memory (HBM), optical devices, processors or other IC logic structures. The IC dies 202 containing the functional circuitry 214 may optionally include optical devices such as photo-detectors, lasers, optical sources, and the like. In some examples, at least one of the IC dies 202 is a logic die having functional circuitry 214 configured as a math processor (also known as math engine) circuitry for accelerating machine-learning math operations in hardware, such as self-driving cars, artificial intelligence and data-center neural-network applications.

The functional circuitry 214 terminates at contact pads 226 on the active side 206 of the wafer 200. Although only two contact pads 226 are illustrated in FIG. 2B, it is commonly known that each IC die 202 includes many, many contact pads 226.

A hybrid bonding layer 220 is disposed over the active portion 210, including the contact pads 226. The hybrid bonding layer 220 includes metal pads 216 disposed on and in electrical contact with the contact pads 226. Each metal pad 216 is formed on and electrically connected to a respective one of the contact pads 226. In one example, the metal pad 216 is formed from plated copper that is disposed on a copper seed layer. Each metal pad 216 is separated by an external dielectric layer 218. The dielectric layer 218 is selected from a material suitable for hybrid bonding to another dielectric material present on a different wafer. In one example, the dielectric layer 218 is polybenzoxazole (PBO), polyimide (PI), benzocyclobutene (BCB), a combination thereof or the like. The dielectric layer 218 and the metal pads 216 are exposed on the active side 206 of the wafer 200 to facilitate bonding to a hybrid bonding layer formed on another wafer as the wafers are stacked to together, connecting the functional circuitries 214 of the stacked dies 202 as later described.

The active portion 210 is formed on a substrate 212. The substrate 212 may be a silicon wafer, a germanium wafer, a plastic substrate, a glass substrate or other suitable substrate upon which the active portion 210 is formed. The substrate 212 has a backside 208 defining the opposite side of the wafer 200 relative to the active side 206. A plurality of contact pads 224 are formed and exposed on the backside 208 of the wafer 200. The contact pads 224 are coupled by metal filled vias 222 formed through the substrate 212 to the functional circuitry 214 of the IC die 202.

In preparation of the following description of the method 100, attention is first directed to FIG. 2C which illustrates a first wafer 230 and a second wafer 232 that will later become part of a stack of wafers. Each wafer 230, 232 is configured as the wafer 200 described above. The first and second wafers 230, 232 may or may not be identical, but are configured to have their IC dies 202 and scribe lanes 204 aligned when stacked together. Although not shown in FIG. 2C, the hybrid bonding layer 220 is present on the active side 206 of each wafer 230, 232 (such as illustrated the wafer 200 shown in FIG. 2B).

The method 100 begins at operation 102 by depositing a warpage compensating layer 234 on the backside 208 of at least one of the first and second wafers 230, 232, as illustrated in FIG. 2D. In FIG. 2D, both wafers 230, 232 include a warpage compensating layer 234 disposed on the backside 208. The warpage compensating layer 234 disposed on each of the wafers 230, 232 may be the same or different material. The warpage compensating layer 234 may be a dielectric material or a metal material. Non-limiting examples of dielectric materials suitable for use as the warpage compensating layer 234 include nitrides and oxides, such as silicon nitride and silicon oxide. Non-limiting examples of metal materials suitable for use as the warpage compensating layer 234 include aluminum, nickel and copper.

The material, materials properties and/or thickness of the warpage compensating layer 234 may be selected to mitigate warpage of the stacked IC dies 202 after the wafers 230, 232 so that additional processing may be perform on the stack of wafers without exceeding processing or processing tool design limits. The warpage compensating layer 234 may be deposited by low temperature techniques, such as plasma enhanced physical vapor deposition or other suitable technique.

At operation 104, the active side 206 of the first wafer 230 is stacked on the active side 206 of the second wafer 232 to form a wafer stack 236, as illustrated in FIGS. 2E-2F. Although not clearly shown in FIG. 2F, the hybrid bonding layers 220 of each wafer 230, 232 are aligned such the facing pads 216 of the stacked wafers 230, 232 facilitate electrically connecting the functional circuitry 214 of the first wafer 230 to the functional circuitry 214 of the second wafer 232.

At operation 104, the wafers 230, 232 undergo a hybrid bonding process that includes forming non-metal to non-metal bonds using fusion bonding, and forming metal-to-metal bonds. The non-metal to non-metal bonds are formed between the dielectric layers 218 exposed on the active side 206 of the facing wafers 230, 232. The metal-to-metal bonds between the facing pads 216 may be formed using pressure and heat to form eutectic metal bonds. In one example, a hybrid bond is formed by bonding the dielectric layers 218 surrounding the bond pads 216 to first secure the wafers 230, 232, followed by an interfusion of the metal materials of the bond pads 216 to create the electric interconnect between the functional circuitry 214 of the IC dies 202 on the first wafer 230 to the functional circuitry 214 of the of the IC dies 202 on the second wafer 232.

At operation 106, the warpage compensating layer 234 is removed from the backside 208 of at least one or both of the wafers 230, 232 prior to dicing the first wafer prior dicing the wafer stack 236. In the example illustrated in FIG. 2F, the warpage compensating layer 234 is removed from the backside 208 of the first wafer 230, while remaining on the second wafer 232. The warpage compensating layer 234 remaining on the backside 208 of the second wafer 232 may optionally be removed prior to dicing. The warpage compensating layer 234 is removed from the backside 208 using any suitable technique. For example, the warpage compensating layer 234 may be removed by etching, grinding, milling or other technique.

Optionally at operation 106, the substrate 212 may be thinned during or after the warpage compensating layer 234 is removed. In the example depicted in FIG. 2G, the substrate 212 is thinned as part of the grinding process that removes the warpage compensating layer 234 from the first wafer 230. One or both wafers 230, 232 may be thinned. Optionally, the warpage compensating layer 234 remaining on the backside 208 of the second wafer 232 may optionally be removed prior to dicing.

At operation 108, at least a third wafer 238 is added to the wafer stack 236, as illustrated in FIGS. 2H-2I. The third wafer 238 may be configured as described with reference to the wafer 200. The third wafer 238 may be configured the same one or more of wafers 230, 232. Alternatively, the third wafer 238 may be configured differently than one or all of wafers 200, 230, 232. The third wafer 238 may optionally include a warpage compensating layer 234 on a side of the third wafer 238 that is not stacked against the other wafers 230, 232. The third wafer 238 is not mounted a warpage compensating layer 234, but rather on a surface of one of the wafers 230, 232 that (a) had the warpage compensating layer 234 removed; (b) never had a warpage compensating layer 234 disposed thereon, or (c) on a thinned surface of the substrate 212 exposed on the wafer stack 236. In the example depicted in FIGS. 2H-2I, the active side 206 of the third wafer 238 is mounted to the backside 208 of the first wafer 230. Alternatively, the backside 208 of the third wafer 238 may be mounted to the backside 208 of the first wafer 230.

The third wafer 238 is not mounted a warpage compensating layer 234, but rather on a surface of one of the wafers 230, 232. The functional circuitry 214 of the third wafer 238 is electrically connected, for example by solder connections or hybrid bonding, to the functional circuitry 214 of the wafer 230, 232 to which the third wafer 238 is mounted.

One or more of operations 102, 104, 106, 108 may be repeated to stack 4, 5 or even more wafers together to form the wafer stack 236. The additional wafers may be configured as any one or combination of the wafers 200, 230, 232 and/or 238. The addition wafers may be stack in any suitable orientation, such as active side 206 to active side 206, active side 206 to backside 208, the backside 208 to backside 208, or any combination thereof.

In one example, first and second end surfaces 242, 244 of the wafer stack 236 do not have an exposed warpage compensating layer 234. For example, during the formation of the wafer stack 236, all of the warpage compensating layers 234 have been removed after stacking. In another example, the wafer stack 236 has an exposed warpage compensating layers 234 on the first end surface 242 of the wafer stack 236 as shown in FIG. 21. In such an example, the exposed warpage compensating layers 234 on the first end surface 242 of the wafer stack 236 may be a metal layer to promote heat transfer away from the wafer stack 236 when the IC dies 202 are in use.

At operation 110, the wafer stack 236 is diced along the scribe lanes 204 to form a plurality of stacked integrated circuit devices 240, as illustrated in FIG. 2J. The wafer stack 236 may be diced using a wire saw, laser or other suitable cutting technique. Each stacked integrated circuit device 240 includes at least one IC die 202 from each wafer comprising the wafer stack 236.

At operation 112, at least one of the plurality of stacked integrated circuit devices 240 is mounted on a substrate 250 to form a chip package 260. The substrate 250 may be a package substrate, or optionally, an interposer soldered to a package substrate. The stacked integrated circuit device 240 may be mounted on the substrate 250 using solder connections 252 or other suitable connection to electrically connect the functional circuitry of the IC dies 202 of the stacked integrated circuit device 240 with the routing circuitry of the substrate 250. Similarly, solder balls 254 or other suitable connection may be utilized to couple the routing circuitry of the substrate 250 to routing circuitry of a print circuit board (PCB) 268 (shown in phantom), connecting the chip package 260 to the PCB 268 to form an electronic device. In the example depicted in FIG. 2K, a metal warpage compensating layer 234 is shown disposed on the top surface of the chip package 260 to enhance cooling of the IC dies 202 of the stacked integrated circuit device 240 of the chip package 260. As discussed above, the warpage compensating layer 234 alternatively may be removed from the stacked integrated circuit device 240 so that no warpage compensating layer 234 remains in or on the chip package 260.

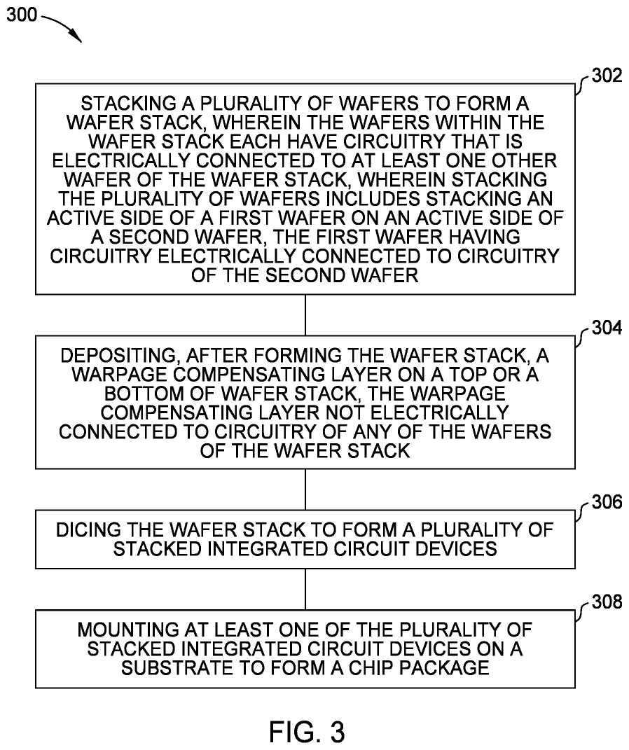

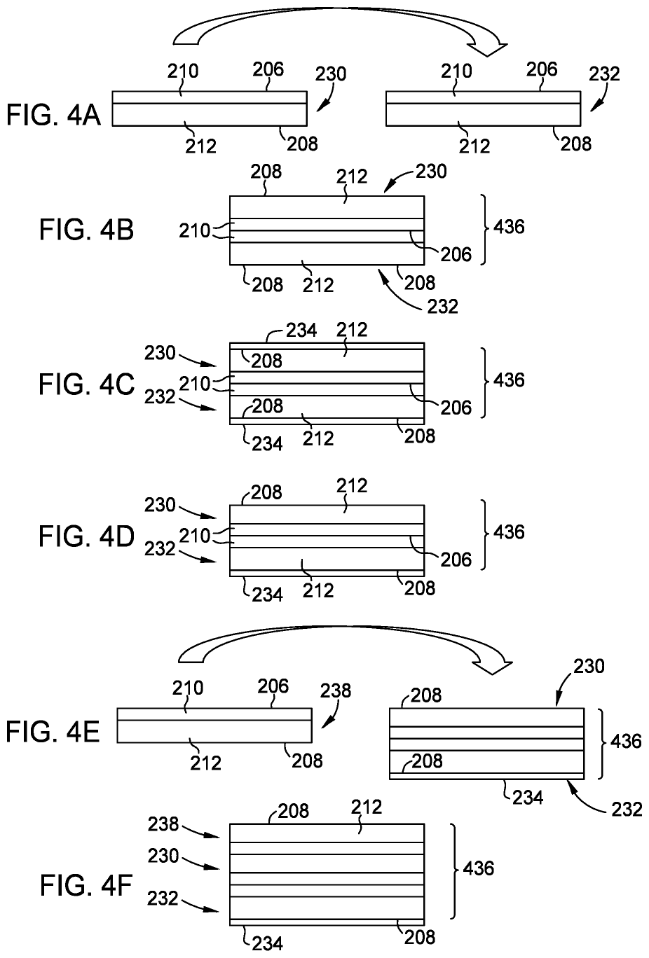

FIG. 3 is a flow diagram of another method 300 for forming a chip package, such as chip package 260 illustrated in 2K, or in other chip package having a configuration suitable for stacking. FIGS. 4A-4K are schematic representations of wafers being stacked, diced to form stacked IC devices, and mounting at least one of the stacked IC devices to form a chip package in accordance to the method 300 of FIG. 3.

The exemplary wafer 200 illustrated in FIG. 2A or other suitable wafer may be utilized to perform the method 300. The method 300 begins at operation 302 by stacking a plurality of wafers 230, 232 to form a wafer stack 436, as illustrated in FIGS. 4A-4B. None of the wafers 230, 232 include a warpage compensating layer as described herein prior to forming the wafer stack 436. Each of the wafers 230, 232 within the wafer stack 436 have functional circuitry 214 (of the IC dies 202) that is electrically connected to at least one other wafer of the wafer stack 436. Stacking the plurality of wafers 230, 232 includes stacking an active side 206 of the first wafer 230 on an active side 206 of a second wafer 232, such that the functional circuitry 214 of the first wafer 230 is electrically connected to functional circuitry 214 of the second wafer 232.

At operation 304 and after forming the wafer stack 436 at operation 302, a warpage compensating layer 234 is deposited on at least one of a top or a bottom the wafer stack 436, as illustrated in FIG. 4C. The warpage compensating layer 234 is not electrically connected to the functional circuitry 214 of any of the IC dies 202 of the wafers 230, 232 comprising of the wafer stack 436. Although the warpage compensating layer 234 is shown deposited on a wafer stack 436 having only two wafers, the warpage compensating layer 234 may be first deposited on the wafer stack 436 after one or more additional wafers have been added to the wafer stack 436.

Prior to dicing the dicing the wafer stack 436 comprising the wafers 230, 232, one or more additional wafer 238 may be added to the wafer stack 436. Prior to adding an additional wafer 238, the warpage compensating layer 234 if present on at least the surface of the wafer stack 436 on which the additional wafer 238 is to be mounted is removed, as illustrated in FIG. 4D. Optionally, the warpage compensating layer 234 if present on the opposite surface of the wafer stack 238 may also be removed.

The addition of at least the third wafer 238 to the wafer stack 236 is illustrated in FIGS. 4E-4F. The third wafer 238 may be configured as described above. The third wafer 238 may optionally include a warpage compensating layer 234 on a side of the third wafer 238 that is not stacked against the other wafers 230, 232. The third wafer 238 is not mounted a warpage compensating layer 234, but rather on a surface of one of the wafers 230, 232 that (a) had the warpage compensating layer 234 removed; (b) never had a warpage compensating layer 234 disposed thereon, or (c) on a thinned surface of the substrate 212 exposed on the wafer stack 236. In the example depicted in FIGS. 4E-4F, the active side 206 of the third wafer 238 is mounted to the backside 208 of the first wafer 230. Alternatively, the backside 208 of the third wafer 238 may be mounted to the backside 208 of the first wafer 230.

The third wafer 238 is not mounted a warpage compensating layer 234, but rather on a surface of one of the wafers 230, 232. The functional circuitry 214 of the third wafer 238 is electrically connected, for example by solder connections or hybrid bonding, to the functional circuitry 214 of the wafer 230, 232 to which the third wafer 238 is mounted.

One or more of operations 302, 304 may be repeated to stack 4, 5 or even more wafers together to form the wafer stack 236. The additional wafers may be configured as any one or combination of the wafers 200, 230, 232 and/or 238. The addition wafers may be stack in any suitable orientation, such as active side 206 to active side 206, active side 206 to backside 208, the backside 208 to backside 208, or any combination thereof.

At operation 306, the wafer stack 436 is diced to form a plurality of stacked integrated circuit devices 240, similar to as illustrated with reference to the wafer stack 236 illustrated in FIG. 2J. The wafer stack 436 may be diced using a wire saw, laser or other suitable cutting technique. Each stacked integrated circuit device 240 includes at least one IC dies 202 from each wafer comprising the wafer stack 436.

At operation 308, at least one of the stacked integrated circuit devices 240 is mounted on a substrate 250 to form a chip package 260, as illustrated in FIG. 2K. The substrate 250 may be a package substrate, or optionally, an interposer soldered to a package substrate. The stacked integrated circuit device 240 may be mounted on the substrate 250 using solder connections 252 or other suitable connection to electrically connect the functional circuitry of the IC dies 202 of the stacked integrated circuit device 240 with the routing circuitry of the substrate 250. Similarly, solder balls 254 or other suitable connection may be utilized to couple the routing circuitry of the substrate 250 to routing circuitry of a print circuit board (PCB) 268 (shown in phantom), connecting the chip package 260 to the PCB 268 to form an electronic device. In the example depicted in FIG. 2K, a metal warpage compensating layer 234 is shown disposed on the top surface of the chip package 260 to enhance cooling of the IC dies 202 of the stacked integrated circuit device 240. As discussed above, the warpage compensating layer 234 alternatively be removed from the stacked integrated circuit device 240 so that no warpage compensating layer 234 remains in or on the chip package 260.

Thus, techniques have been disclosed herein that mitigate warpage when stacking wafers that are later diced to form chip stacks. The chip stacks are used to form chip packages and electronic devices. The techniques employ a warpage compensation film deposited on an exposed surface of a wafer prior to or after wafer stacking. The warpage compensation film can be selected to best mitigate warpage in the wafer stack, for example, by choosing materials, material properties and/or the thickness of the warpage compensation film to effectively produce a flatter wafer stack as compared to conventional techniques. The flatter wafer stack results in a more robust and reliable chip package. The techniques described above can also be implemented and tuned at almost any point during the design cycle, which beneficially reduces both development costs and time to market.

While the foregoing is directed to embodiments of the present invention, other and further embodiments of the invention may be devised without departing from the basic scope thereof, and the scope thereof is determined by the claims that follow.

What is claimed is:

1. A method for mitigating warpage on stacked wafers, the method comprising:
depositing a first warpage compensating layer on a backside of a first wafer;
stacking an active side of the first wafer on an active side of a second wafer to form a wafer stack having circuitry of the first wafer electrically connected to circuitry of the second wafer; and
removing the first warpage compensating layer from the backside of the first wafer prior dicing the wafer stack.

2. The method of claim 1, wherein depositing the first warpage compensating layer on the backside of the first wafer further comprises:
depositing a dielectric film.

3. The method of claim 1 further comprising:
depositing a second warpage compensating layer on a backside of the second wafer.

4. The method of claim 3, wherein depositing the second warpage compensating layer on the backside of the second wafer further comprises:
depositing a dielectric film.

5. The method of claim 4 further comprising:
removing the second warpage compensating layer from the backside of the second wafer prior dicing the wafer stack.

6. The method of claim 4, wherein depositing the second warpage compensating layer on the backside of the second wafer further comprises:
depositing an exposed metal film.

7. The method of claim 6 further comprising:
dicing the wafer stack to form a plurality of stacked integrated circuit devices, wherein dicing cuts through the exposed metal film.

8. The method of claim 1 further comprising:
stacking an active side of a third wafer on the backside of the second wafer to add to the wafer stack, the circuitry of the third wafer electrically connected to circuitry of the second wafer.

9. The method of claim 8 further comprising:
depositing a third first warpage compensating layer on a backside of third second wafer.

10. The method of claim 9, wherein depositing the third warpage compensating layer on the backside of the first wafer further comprises:
depositing a dielectric film.

11. The method of claim 10 further comprising:
removing the third warpage compensating layer from the backside of the third wafer prior dicing the wafer stack.

12. The method of claim 9, wherein depositing the second warpage compensating layer on the backside of the second wafer further comprises:
depositing an exposed metal film.

13. The method of claim 12 further comprising:
dicing the wafer stack to form a plurality of stacked integrated circuit devices, wherein dicing cuts through the exposed metal film.

14. The method of claim 8 wherein the first warpage compensating layer is deposited after forming the wafer stack.

15. The method of claim 8 wherein the first warpage compensating layer is deposited after forming the wafer stack.

16. The method of claim 1 wherein the first warpage compensating layer is deposited after forming the wafer stack.

17. A method for mitigating warpage on stacked wafers, the method comprising:
stacking a plurality of wafers to form a wafer stack, wherein the wafers within the wafer stack each have circuitry that is electrically connected to at least one other wafer of the wafer stack, wherein stacking the plurality of wafers includes stacking an active side of a first wafer on an active side of a second wafer, the first wafer having circuitry electrically connected to circuitry of the second wafer;
depositing, after forming the wafer stack, a warpage compensating layer on a top or a bottom the wafer stack, the warpage compensating layer not electrically connected to circuitry of any of the wafers of the wafer stack; and
dicing the wafer stack.

18. The method of claim 17 further comprising:
removing the warpage compensating layer prior dicing the wafer stack.

19. The method of claim 17, wherein dicing the wafer stack further comprises:
cutting through the exposed metal film.

20. A method for mitigating warpage on stacked wafers, the method comprising:
stacking an active side of a first wafer on an active side of a second wafer, the first wafer having circuitry electrically connected to circuitry of the second wafer;
depositing a dielectric warpage compensating layer on a backside of the second wafer;
thinning the second wafer and removing the warpage compensating layer from the backside of the second wafer prior;
stacking an active side of a third wafer on backside of the thinned second wafer to form a wafer stack comprising the first, second and third wafers, the third wafer having circuitry electrically connected to circuitry of the second wafer; and
dicing the wafer stack.
